(19) United States
(12) Patent Application Publication
(10) Pub. No.: US 2026/0282963 A1
(43) Pub. Date: Sep. 17, 2026

(54) PACKAGE COMPRISING ELONGATED LANDING PAD INTERCONNECTS AND/OR ELONGATED PILLAR INTERCONNECTS

(71) Applicant: QUALCOMM Incorporated, San Diego, CA (US)

(72) Inventors: Yangyang SUN, San Diego, CA (US); Xuefeng ZHANG, San Diego, CA (US); Lily ZHAO, San Diego, CA (US); Huxiao XIE, San Diego, CA (US); Maria Cecilia Hernandez ALCIRA, San Diego, CA (US)

(21) Appl. No.: 19/080,653

(22) Filed: Mar. 14, 2025

(51) Int. Cl. H01L 23/00; H01L 23/498

(52) U.S. Cl. CPC H10W 70/65; H10W 70/69; H10W 72/222; H10W 72/227; H10W 72/232; H10W 72/248; H10W 90/724

(57) ABSTRACT

A package comprising a substrate comprising at least one dielectric layer; and a plurality of interconnects comprising: a first plurality of landing pad interconnects, wherein at least one landing pad interconnect from the first plurality of landing pad interconnects has an elongated planar shape; and a second plurality of landing pad interconnects, wherein at least one landing pad interconnect from the second plurality of landing pad interconnects has an elongated planar shape; and an integrated device coupled to the first plurality of landing pad interconnects and the second plurality of landing pad interconnects.

### FIELD

Various features relate to packages and substrates.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages and substrates.

One example provides a package comprising a substrate comprising at least one dielectric layer; and a plurality of interconnects comprising: a first plurality of landing pad interconnects, wherein at least one landing pad interconnect from the first plurality of landing pad interconnects has an elongated planar shape; and a second plurality of landing pad interconnects, wherein at least one landing pad interconnect from the second plurality of landing pad interconnects has an elongated planar shape; and an integrated device coupled to the first plurality of landing pad interconnects and the second plurality of landing pad interconnects.

Another example provides an integrated device comprising a die substrate; a die interconnection portion coupled to the die substrate; a plurality of pad interconnects coupled to the die interconnection portion; and a plurality of pillar interconnects coupled to the plurality of pad interconnects, wherein the plurality of pillar interconnects comprise: a first plurality of pillar interconnects, wherein at least pillar interconnect from the first plurality of pillar interconnects has an elongated planar shape; and a second plurality of pillar interconnects, wherein at least pillar interconnect from the second plurality of pillar interconnects has an elongated planar shape.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes an integrated device and a substrate comprising landing pad interconnects.

FIG. 2 illustrates an exemplary cross sectional plan view of a package that includes a substrate comprising landing pad interconnects.

FIG. 3A illustrates an exemplary close up profile view of a package that includes an integrated device and a substrate comprising landing pad interconnects.

FIG. 3B illustrates an exemplary cross sectional plan view of a substrate comprising a landing pad interconnect.

FIG. 4 illustrates an exemplary cross sectional profile view of a package comprising a substrate coupled to an integrated device comprising pillar interconnects.

FIG. 5 illustrates an exemplary cross sectional plan view of an integrated device comprising pillar interconnects.

FIGS. 6A-6E illustrate an exemplary sequence for fabricating a substrate that includes landing pad interconnects.

FIG. 7 illustrates an exemplary flow diagram of a method for fabricating a substrate that includes landing pad interconnects.

FIGS. 8A-8C illustrate an exemplary sequence for fabricating an integrated device that includes pillar interconnects.

FIG. 9 illustrates an exemplary flow chart of a method for fabricating an integrated device that includes pillar interconnects.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate comprising at least one dielectric layer; and a plurality of interconnects comprising: a first plurality of landing pad interconnects, wherein at least one landing pad interconnect from the first plurality of landing pad interconnects has an elongated planar shape; and a second plurality of landing pad interconnects, wherein at least one landing pad interconnect from the second plurality of landing pad interconnects has an elongated planar shape; and an integrated device coupled to the first plurality of landing pad interconnects and the second plurality of landing pad interconnects. The elongated landing pad interconnects help provide interconnects that are closer to each other, which allows higher density interconnects. This in turn may help improve the performance of the package, while providing a package with a compact form factor. Moreover, the elongated landing pad interconnects may be configured, aligned, oriented in such a way to make the package more resistant to stress and/or delamination.

### Exemplary Package Comprising a Substrate with Elongated Landing Pad Interconnects and/or Integrated Device with Elongated Pillar Interconnects

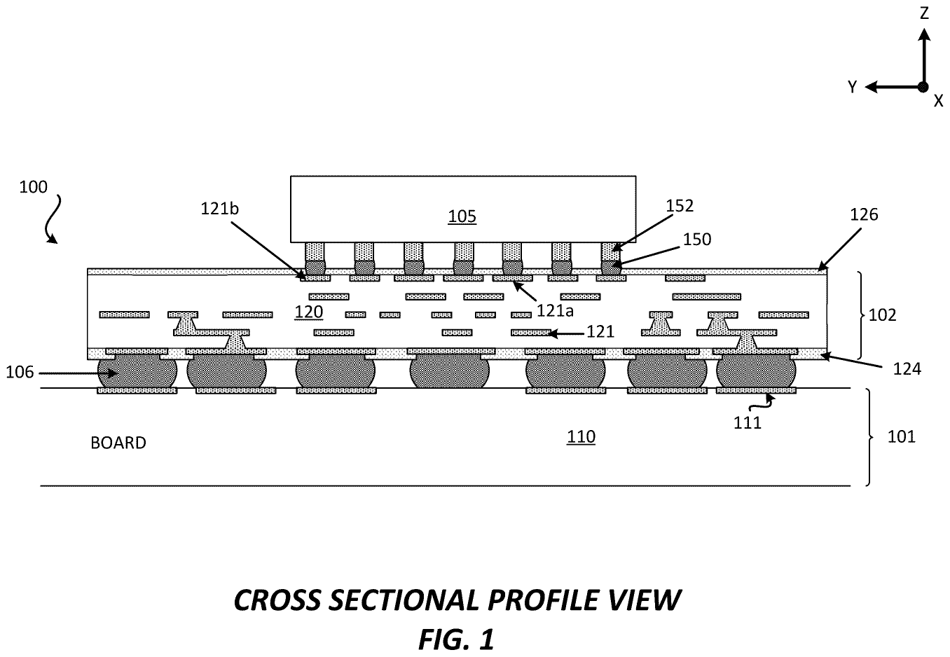

FIG. 1 illustrates a cross sectional profile view of a package 100 that includes an integrated device and a substrate. The integrated device may include elongated pillar interconnects. The substrate may include elongated landing pad interconnects. The package 100 is coupled to a board 101 through a plurality of solder interconnects 106. The board 101 includes at least one board dielectric layer 110 and a plurality of board interconnects 111. The board 109 may include a printed circuit board (PCB).

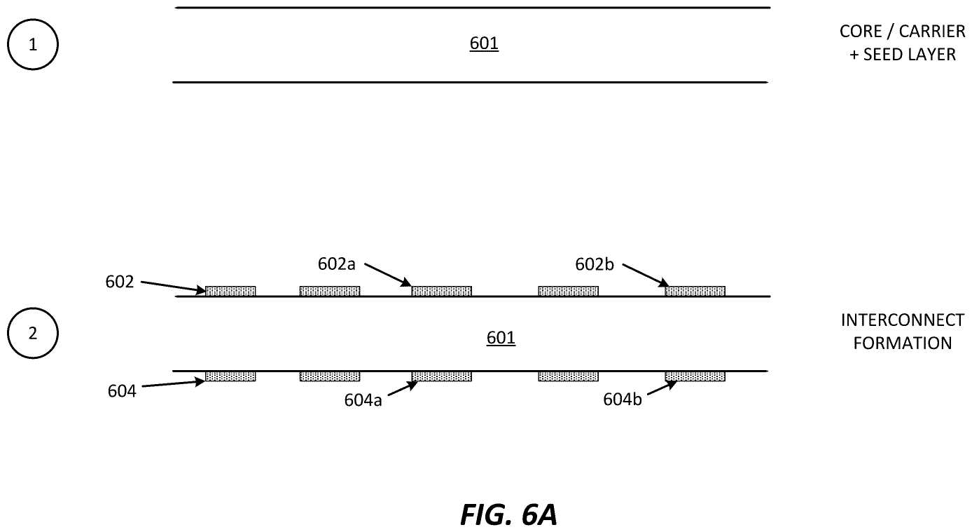

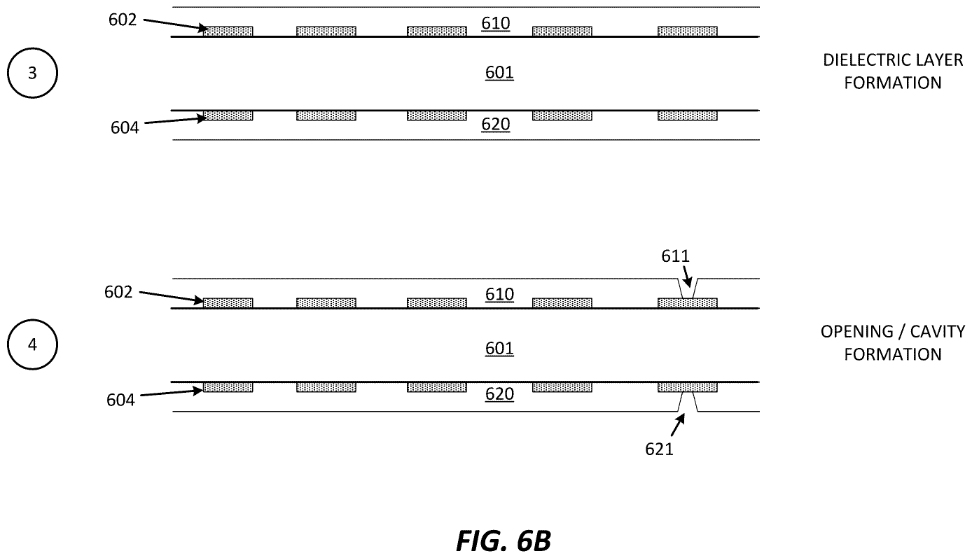

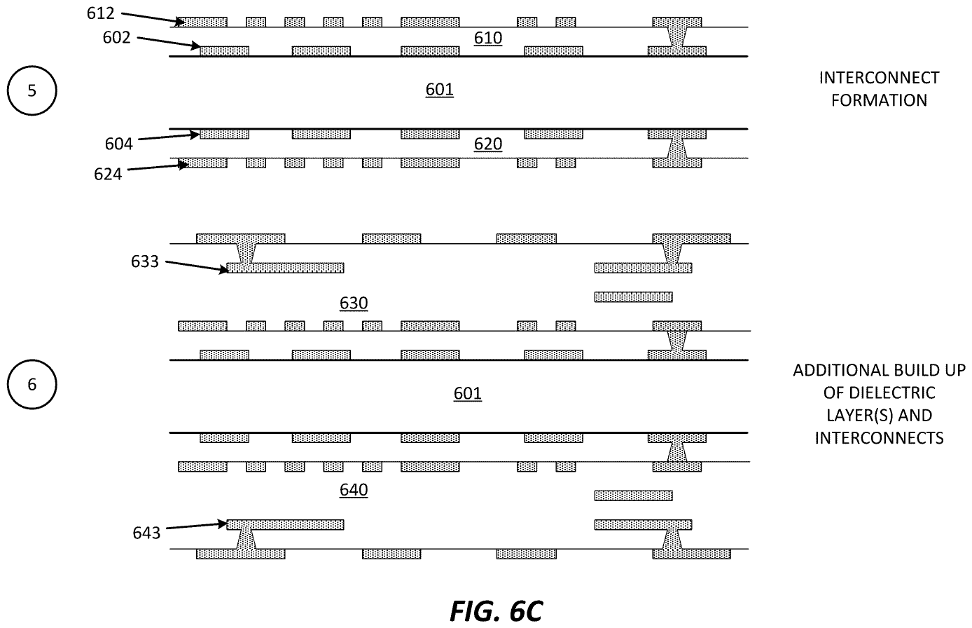

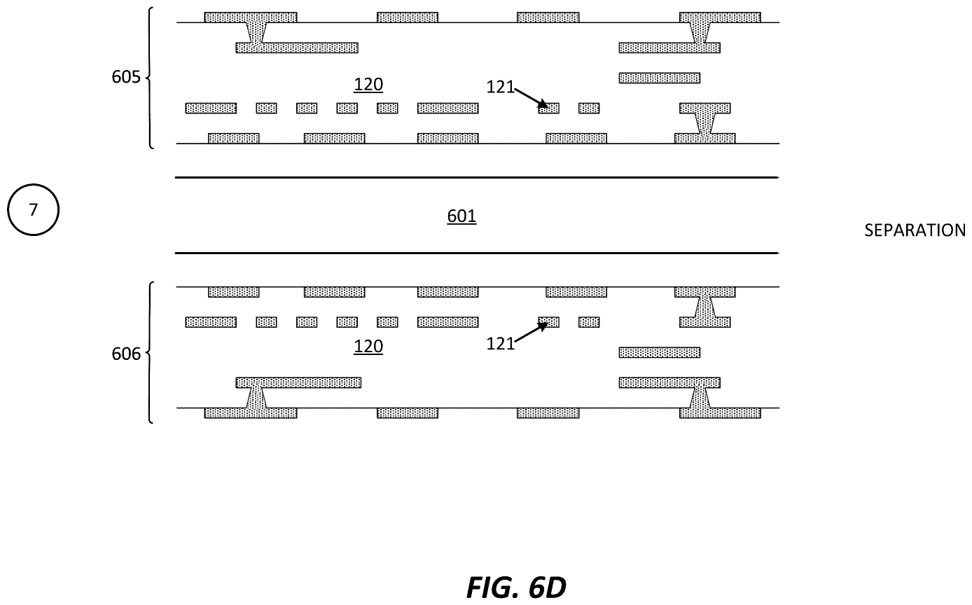

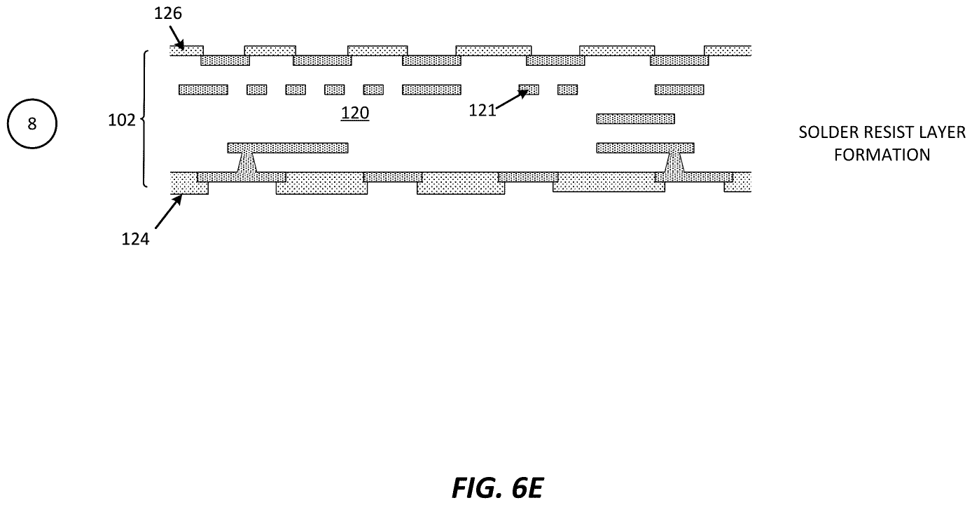

The package 100 may include a substrate 102 and an integrated device 105. The substrate 102 may be a coreless substrate. However, different implementations may use different substates. The substrate 102 may include at least one dielectric layer 120, a plurality of interconnects 121, a solder resist layer 124 and a solder resist layer 126. The plurality of interconnects 121 may include a plurality of landing pad interconnects 121a. The plurality of landing pad interconnects 121a may include one or more landing pad interconnects that are elongated landing pad interconnects. The plurality of landing pad interconnects 121a may include one or more landing pad interconnects that have an oblong planar shape and/or an elongated planar shape. In some implementations, the plurality of landing pad interconnects 121a may include one or more landing pad interconnects that have a circular planar shape (e.g., non-elongated planar shape). The plurality of landing pad interconnects 121a may include one or more landing pad interconnects that have a planar length and a planar width, where the planar length may be longer and/or greater than the planar width. A landing pad interconnect may be a pad interconnect that is coupled to and touching a solder interconnect and/or a solder bump interconnect. FIGS. 6A-6E illustrate an example of a process for fabricating a substrate that includes landing pad interconnects with an oblong planar shape and/or an elongated planar shape.

The integrated device 105 is coupled to the substrate 102 through a plurality of pillar interconnects 152 and/or a plurality of solder interconnects 150. For example, the integrated device 105 may be coupled to a plurality of landing pad interconnects through a plurality of pillar interconnects 152 and/or a plurality of solder interconnects 150, where the plurality of landing pad interconnects 121a have an elongated planar shape and/or an oblong planar shape. In some implementations, one or more pillar interconnect from the plurality of pillar interconnects 152 may include an elongated planar shape and/or an oblong planar shape. In some implementations, the plurality of pillar interconnects 152 may include one or more pillar interconnects that have a circular planar shape (e.g., non-elongated planar shape). The plurality of pillar interconnects 152 may include one or more pillar interconnects that have a planar length and a planar width, where the planar length may be longer and/or greater than the planar width.

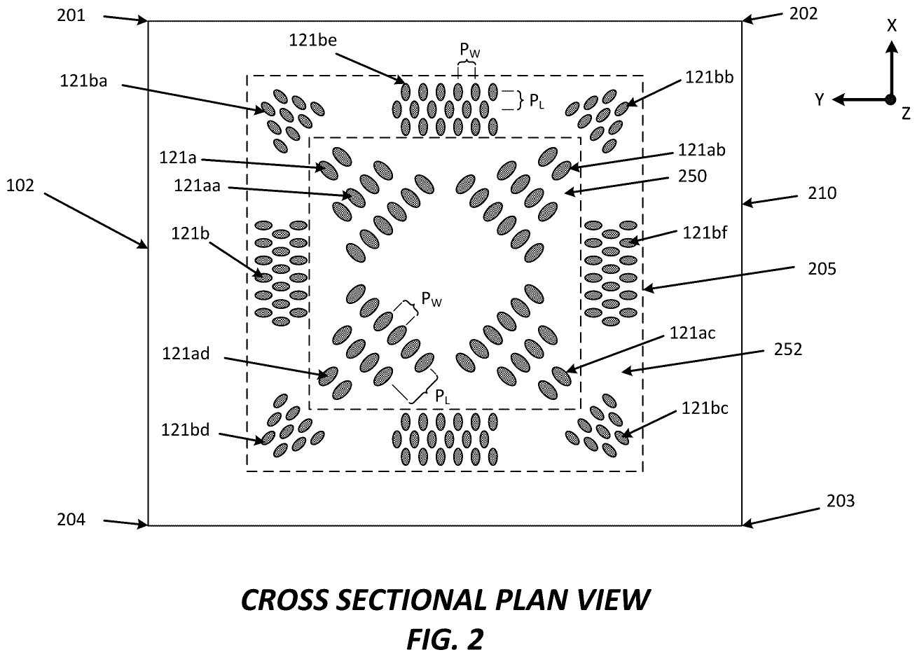

FIG. 2 illustrates a cross sectional plan view of the substrate 102. In particular, FIG. 2 illustrates a substrate that includes a plurality of landing pad interconnects 121a and a plurality of landing pad interconnects 121b. The plurality of landing pad interconnects 121a and the plurality of landing pad interconnects 121b may be considered part of the plurality of interconnects 121 of the substrate 102.

The plurality of landing pad interconnects 121a and the plurality of landing pad interconnects 121b vertically overlap with the integrated device 105. The substrate 102 includes a portion 205. The portion 205 of the substrate 102 may represent the portion of the substrate 102 that vertically overlaps with the integrated device 105. The portion 205 includes a portion 250 and a portion 252. The portion 250 may represent a portion of the substrate 102 that vertically overlaps with a core portion of the integrated device 105. The core portion of the integrated device 105 may include pillar interconnects (and/or coupled to pillar interconnects) that are configured to provide electrical paths for power and/or ground. The portion 252 may represent a portion of the substrate 102 that vertically overlaps with a periphery portion of the integrated device 105. The periphery portion of the integrated device 105 may include pillar interconnects (and/or coupled to pillar interconnects) that are configured to provide electrical paths for input/output (I/O) signals.

The portion 250 includes the plurality of landing pad interconnects 121a. The plurality of landing pad interconnects 121a include a plurality of landing pad interconnects 121aa, a plurality of landing pad interconnects 121ab, a plurality of landing pad interconnects 121ac and a plurality of landing pad interconnects 121ad. The elongated portion of the landing pad interconnects from the plurality of landing pad interconnects 121aa may be oriented in a first diagonal direction (e.g., relative to a first edge 210 of the substrate 102, towards a first corner 201 of the substrate). The elongated portion of the landing pad interconnects from the plurality of landing pad interconnects 121ab may be oriented in a second diagonal direction (e.g., relative to a first edge 210 of the substrate 102, towards a second corner 202 of the substrate). The elongated portion of the landing pad interconnects from the plurality of landing pad interconnects 121ac may be oriented in a third diagonal direction (e.g., relative to a first edge 210 of the substrate 102, towards a third corner 203 of the substrate). The elongated portion of the landing pad interconnects from the plurality of landing pad interconnects 121ad may be oriented in a fourth diagonal direction (e.g., relative to a first edge 210 of the substrate 102, towards a fourth corner 204 of the substrate). In some implementations, the first diagonal direction may be opposite to the third diagonal direction. In some implementations, the second diagonal direction may be opposite to the fourth diagonal direction. In some implementations, the first diagonal direction may be orthogonal to the second diagonal direction and the fourth diagonal direction. In some implementations, the second diagonal direction may be orthogonal to the first diagonal direction and the third diagonal direction. It is noted that the plurality of landing pad interconnects 121a may include landing pad interconnects that may be oriented in a direction that is parallel or orthogonal to one or more edges of the substrate 102. Thus, one or more landing pad interconnects from the plurality of landing pad interconnects 121a may be oriented and/or aligned in many different directions and are not limited to the example shown in FIG. 2.

The portion 252 includes the plurality of landing pad interconnects 121b. The plurality of landing pad interconnects 121b include a plurality of landing pad interconnects 121ba, a plurality of landing pad interconnects 121bb, a plurality of landing pad interconnects 121bc, a plurality of landing pad interconnects 121bd, a plurality of landing pad interconnects 121be and a plurality of landing pad interconnects 121bf. The elongated portion of the landing pad interconnects from the plurality of landing pad interconnects 121ba may be oriented in a first diagonal direction (e.g., relative to a first edge 210 of the substrate 102, towards a first corner 201 of the substrate). The elongated portion of the landing pad interconnects from the plurality of landing pad interconnects 121bb may be oriented in a second diagonal direction (e.g., relative to a first edge 210 of the substrate 102, towards a second corner 202 of the substrate). The elongated portion of the landing pad interconnects from the plurality of landing pad interconnects 121bc may be oriented in a third diagonal direction (e.g., relative to a first edge 210 of the substrate 102, towards a third corner 203 of the substrate). The elongated portion of the landing pad interconnects from the plurality of landing pad interconnects 121bd may be oriented in a fourth diagonal direction (e.g., relative to a first edge 210 of the substrate 102, towards a fourth corner 204 of the substrate). In some implementations, the first diagonal direction may be opposite to the third diagonal direction. In some implementations, the second diagonal direction may be opposite to the fourth diagonal direction. In some implementations, the first diagonal direction may be orthogonal to the second diagonal direction and the fourth diagonal direction. In some implementations, the second diagonal direction may be orthogonal to the first diagonal direction and the third diagonal direction.

The elongated portion of the landing pad interconnects from the plurality of landing pad interconnects 121be may be oriented in a first direction that is parallel to an edge of the substrate 102 (e.g., a first edge 210 of the substrate 102). The elongated portion of the landing pad interconnects from the plurality of landing pad interconnects 121bf may be oriented in a first direction that is perpendicular to an edge of the substrate 102 (e.g., a first edge 210 of the substrate 102).

It is noted that the configuration of the plurality of landing pad interconnects shown in FIG. 2 is exemplary and is therefore not limited to the example shown in FIG. 2. Other implementations may have other configurations and/or arrangements of the plurality of landing pad interconnects. For example, the substrate 102 may include landing pad interconnects that have circular planar shapes (e.g., non-elongated planar shapes). These landing pad interconnects may be located in the portion 250 and/or the portion 252 of the substrate 102.

In some implementations, the plurality of landing pad interconnects 121a and/or the plurality of landing pad interconnects 121b may have a pitch of about 105 micrometers in a first direction, and a minimum pitch of about 135 micrometers in a second direction. For example, in a direction along a length of a landing pad interconnect, a minimum pitch (P_{L}) may be about 135 micrometers. In some implementations, in a direction along a width of a landing pad interconnect, a minimum pitch (P_{W}) may be about 105 micrometers. The plurality of landing pad interconnects 121a may include individual landing pad interconnects that are longer, wider and/or larger than landing pad interconnects from the plurality of landing pad interconnects 121b. The configuration of the plurality of landing pad interconnects 121a and/or the plurality of landing pad interconnects 121b may be arranged in one or more rows of landing pad interconnects. In some implementations, the configuration of the plurality of landing pad interconnects 121a and/or the plurality of landing pad interconnects 121b may be arranged in one or more staggered rows of landing pad interconnects, such as shown in by the plurality of landing pad interconnects 121b. An elongated planar shape may include an elliptical planar shape and/or an elongated circular planar shape. In some implementations, an elongated planar shape may have a planar length and a planar width, where the planar length is at least 10 percent greater than the planar width. In some implementations, an elongated planar shape may have a planar length and a planar width, where the planar length is at least 25 percent greater than the planar width. In some implementations, an elongated planar shape may have a planar length and a planar width, where the planar length is at least 50 percent greater than the planar width.

The configuration of the plurality of landing pad interconnects 121a and/or the plurality of landing pad interconnects 121b that use an oblong planar shape and/or an elongated planar shape in combination with the diagonal orientation, helps provide interconnects that are closer to each other, which means higher density interconnects in the substrate. This in turn helps provide high performance packages in a compact form factor. Moreover, orienting and/or aligning the landing pad interconnects towards corners of the substrate help provide a more robust package, as the orientation of the landing pad interconnects and/or the orientation of the pillar interconnects help improve the stress that is absorbed by the package (e.g., during the coupling and/or bumping of the integrated device to the substrate).

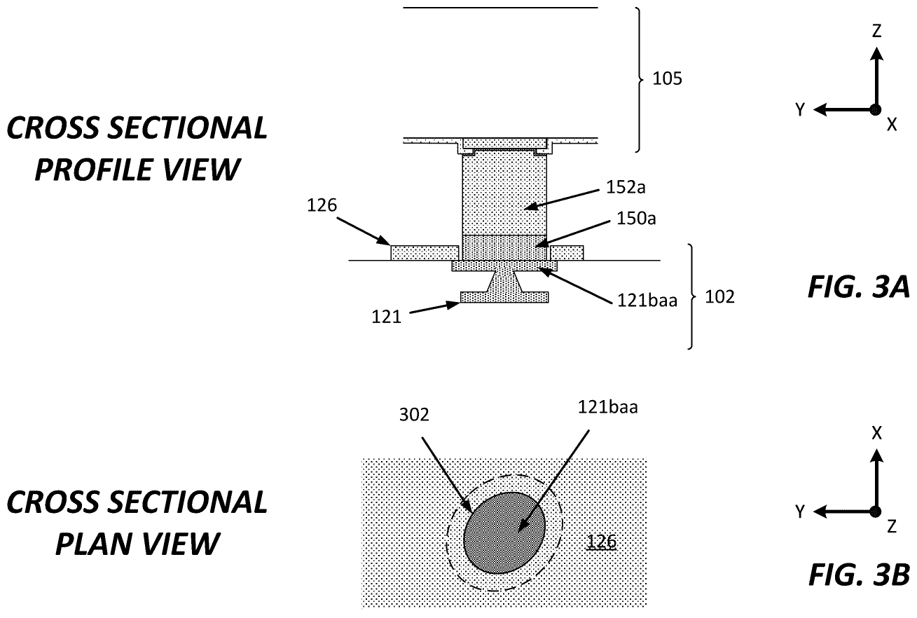

FIG. 3A illustrates a close up profile view of a package that includes an integrated device and a substrate. FIG. 3A illustrates an integrated device 105 that is coupled to the landing pad interconnect 121baa of the substrate 102 through a pillar interconnect 152a and a solder interconnect 150a. The solder interconnect 150a is coupled to and touch the pillar interconnect 152a and the landing pad interconnect 121baa. The landing pad interconnect 121baa may have an elongated planar shape and/or an oblong planar shape. The pillar interconnect 152a may have an elongated planar shape and/or an oblong planar shape. The pillar interconnect 152a may be aligned and/or oriented in a same direction as the landing pad interconnect 121baa.

FIG. 3B illustrates a plan view of the landing pad interconnect 121baa that includes an elongated planar shape and/or an oblong planar shape. The landing pad interconnect 121baa has a planar length that is greater than its planar width. The landing pad interconnect 121baa is at least partially covered by the solder resist layer 126. The solder resist layer 126 includes an opening 302. The opening 302 exposes part of the landing pad interconnect 121baa. The opening 302 in the solder resist layer 126 may have an elongated planar shape and/or an oblong planar shape. The exposed portion (e.g., exposed before solder interconnect is coupled) of the landing pad interconnect 121baa may have an elongated planar shape and/or an oblong planar shape. The landing pad interconnect 121baa may be oriented in a diagonal direction (e.g., relative to an edge of the substrate 102).

In some implementations, pillar interconnects (e.g., 152) may have a planar dimension that is about at least 70 micrometers in length (e.g., planar length) and at least 40 micrometers in width (e.g., planar width). In some implementations, landing pad interconnects (e.g., 121 a, 121 b) may have a planar dimension that is about at least 120 micrometers in length (e.g., planar length and at least 90 micrometers in width (e.g., planar width). In some implementations, openings (e.g., 302) in the solder resist layer (e.g., 126) over landing pad interconnects (e.g., 121a, 121b) may have planar dimension that is about at least 90 micrometers in length (e.g., planar length) and at least 40 micrometers in width (e.g., planar width). In some implementations, a minimum pitch between neighboring landing pad interconnects in the planar width direction is at least 105 micrometers. In some implementations, a minimum pitch between neighboring landing pad interconnects in the planar length direction is at least 135 micrometers. In some implementations, a minimum pitch between neighboring pillar interconnects in the planar width direction is at least 105 micrometers. In some implementations, a minimum pitch between neighboring pillar interconnects in the planar length direction is at least 135 micrometers. However, it is noted that the landing pad interconnects and/or the pillar interconnects may have different dimensions and/or different minimum pitches.

In some implementations, the use of landing pad interconnects with an oblong planar shape and/or an elongated planar shape helps provide high density interconnects that are closer to each other, which can help provide a substrate and/or a package with a compact form factor. This may also help provide a package with improved performances. Moreover, orienting and/or aligning the landing pad interconnects towards corner edges of the substrate help provide a more robust package, as the orientation of the landing pad interconnects and/or the orientation of the pillar interconnects help improve the stress that is absorbed by the package (e.g., during the coupling and/or bumping of the integrated device to the substrate).

### Exemplary Integrated Device Comprising Pillar Interconnects

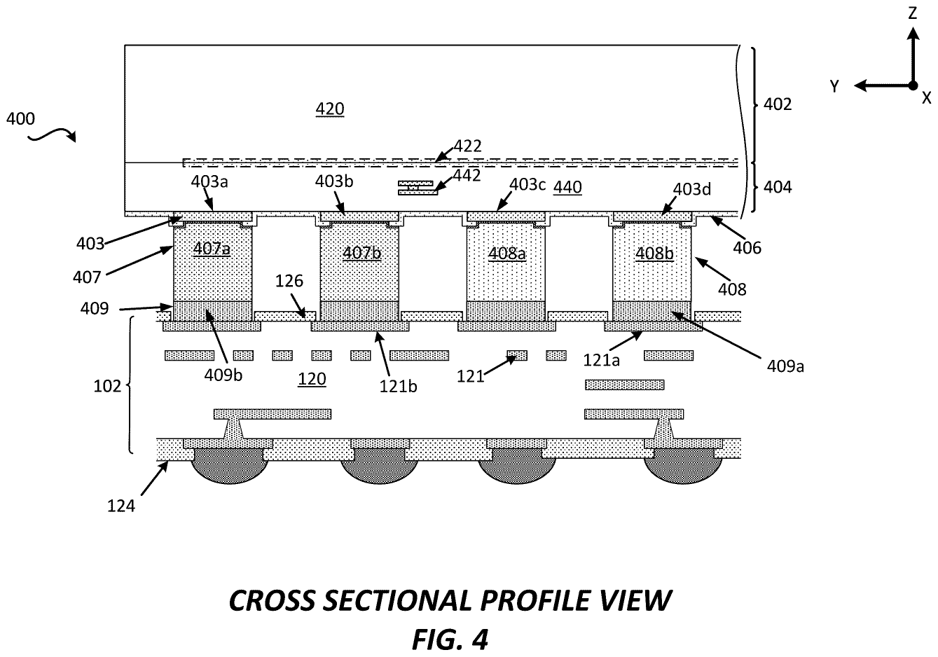

FIG. 4 illustrates a cross sectional profile view of an integrated device 400 that includes at least one pillar interconnect with an elongated planar shape and/or an oblong planar shape. The integrated device 400 may represent the integrated device 105. The integrated device is coupled to the substrate 102. The integrated device 400 includes a die substrate portion 402, and a die interconnection portion 404. The die substrate portion 242 includes a die substrate 420 and an active region 422. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420. The die substrate 420 may include silicon (Si).

The die interconnection portion 404 includes at least one dielectric layer 440 and a plurality of die interconnects 442. The die interconnection portion 404 is coupled to the die substrate portion 402. The plurality of die interconnects 442 are coupled to the active region 422 of the die substrate portion 402. In some implementations, a back end of line (BEOL) process may be used to fabricate the die interconnection portion 404.

The integrated device 400 includes a plurality of pad interconnects 403 and a passivation layer 406. The plurality of pad interconnects 403 and/or the passivation layer 406 may be coupled to the die interconnection portion 404. The plurality of pad interconnects 403 are coupled to the plurality of die interconnects 442. In some implementations, the plurality of pad interconnects 403 and/or the passivation layer 406 may be considered part of the die interconnection portion 404. The plurality of pad interconnects 403 include a pad interconnect 403a, a pad interconnect 403b, a pad interconnect 403c and a pad interconnect 403d. In some implementations, one or more pad interconnects from the plurality of pad interconnects 403 may have an elongated planar shape and/or an oblong planar shape.

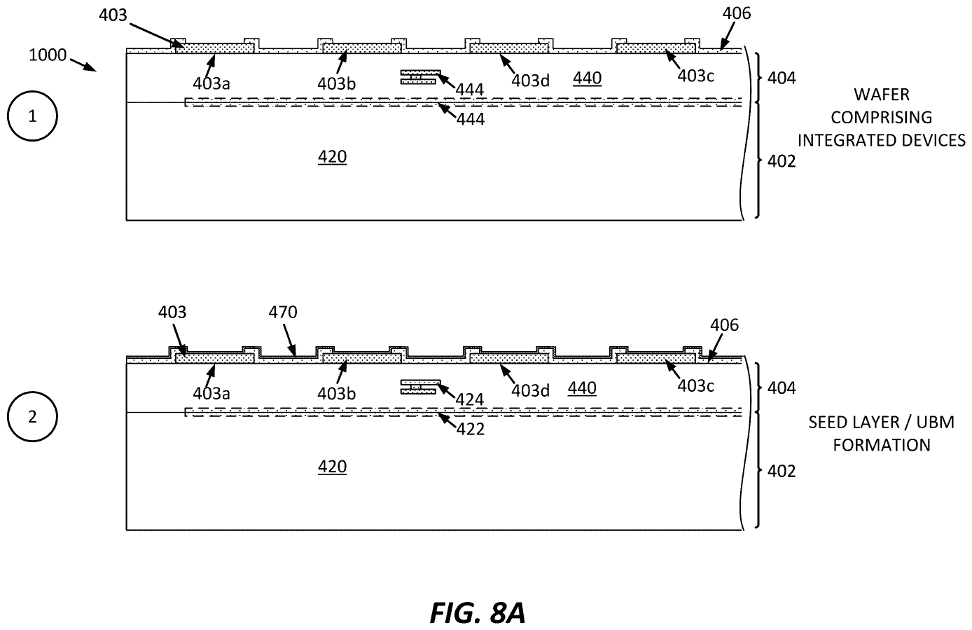

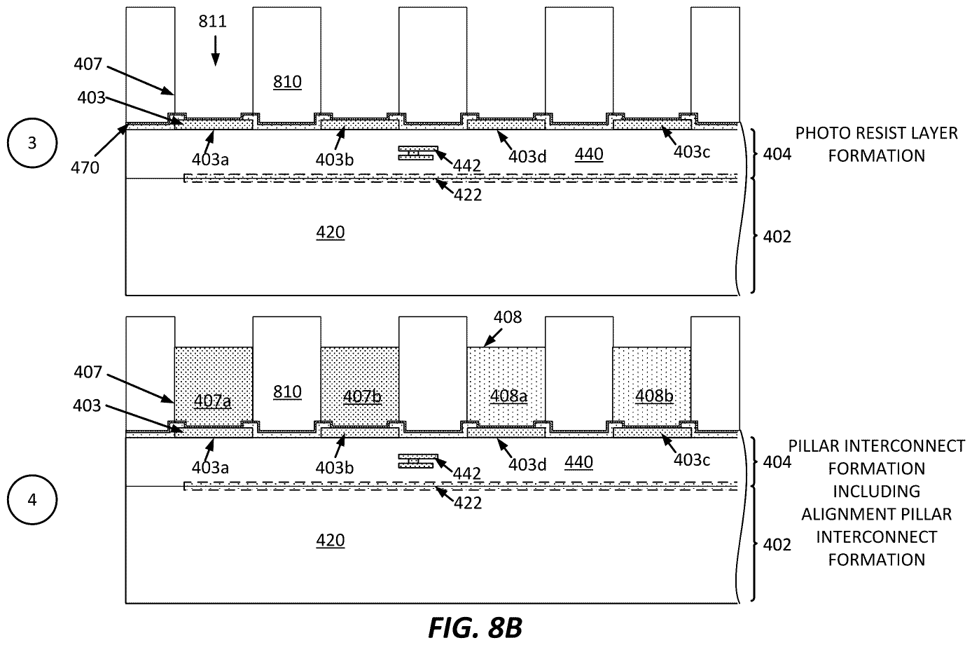

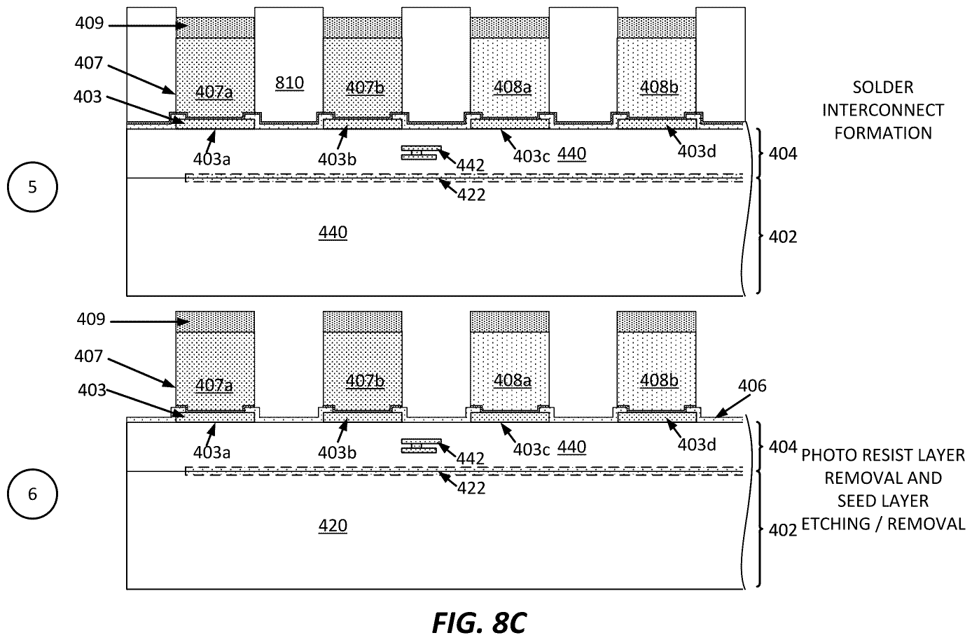

The integrated device 400 includes a plurality of pillar interconnects 407, a plurality of pillar interconnects 408, a plurality of solder interconnects 409. The plurality of pillar interconnects 407 include a pillar interconnect 407a and a pillar interconnect 407b. The plurality of pillar interconnects 408 include a pillar interconnect 408a and a pillar interconnect 408b. The plurality of solder interconnects 409 include a plurality of solder interconnects 409a and a plurality of solder interconnects 409b. The plurality of pillar interconnects 407 may be coupled to and touch the plurality of pad interconnects 403. The plurality of pillar interconnects 408 may be coupled to and touch the plurality of pad interconnects 403. Some of solder interconnects from the plurality of interconnects 409 may be coupled to and touch the plurality of pillar interconnects 407. Some of solder interconnects from the plurality of interconnects 409 may be coupled to and touch the plurality of pillar interconnects 408. The plurality of pillar interconnects 407 may include a seed layer 470. The seed layer 470 may be an under bump metallization interconnect. In some implementations, the under bump metallization interconnect may be considered part of the plurality of pillar interconnects 407. The plurality of pillar interconnects 408 may include a seed layer 470. The seed layer 470 may be an under bump metallization interconnect. In some implementations, the under bump metallization interconnect may be considered part of the plurality of pillar interconnects 408. FIGS. 8A-8C illustrate an example of a process for fabricating an integrated device that includes pillar interconnects with elongated planar shapes.

The plurality of pillar interconnects 407 may be configured to provide electrical paths for input/output (I/O) signals. The plurality of pillar interconnects 407 may include pillar interconnects that comprise an elongated planar shape and/or an oblong shape. For example, the pillar interconnect 407a may have a width and a length in a planar direction (e.g., X-Y plane), where the length (e.g., planar length) is greater than the width (e.g., planar width). The plurality of pillar interconnects 407 may be coupled to the plurality of landing pad interconnects 121b through a plurality of solder interconnects 409b.

The plurality of pillar interconnects 408 may be configured to provide electrical paths for power and/or ground. The plurality of pillar interconnects 408 may include pillar interconnects that comprise an elongated planar shape and/or an oblong shape. For example, the pillar interconnect 408a may have a width and a length in a planar direction (e.g., X-Y plane), where the length (e.g., planar length) is greater than the width (e.g., planar width). The plurality of pillar interconnects 408 may be coupled to the plurality of landing pad interconnects 121a through a plurality of solder interconnects 409a.

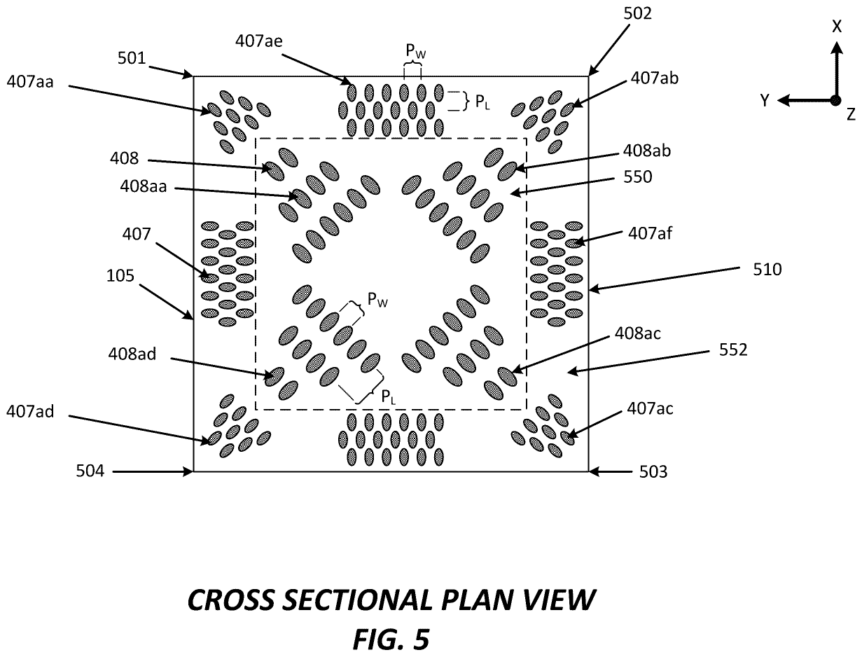

FIG. 5 illustrates a cross sectional plan view of the integrated device 105. In particular, FIG. 5 illustrates an integrated device that includes a plurality of pillar interconnects 407 and a plurality of pillar interconnects 408. The plurality of pillar interconnects 407 and/or the plurality of pillar interconnects 408 may include pillar interconnects with elongated planar shapes and/or oblong planar shapes. The plurality of pillar interconnects 407 may be configured to be coupled to a plurality of landing pad interconnects 121b (of the substrate 102) through a plurality of solder interconnects 409b. The plurality of pillar interconnects 408 may be configured to be coupled to a plurality of landing pad interconnects 121a (of the substrate 102) through a plurality of solder interconnects 409a.

The integrated device 105 includes a portion 550 and a portion 552. The portion 550 may be a core portion of the integrated device 105. The portion 552 may be a periphery portion of the integrated device 105. The portion 550 of the integrated device 105 may vertically overlap with the portion 250 of the substrate 102. The portion 552 of the integrated device 105 may vertically overlap with the portion 252 of the substrate 102.

The portion 550 (e.g., core portion) of the integrated device 105 may include pillar interconnects (and/or coupled to pillar interconnects) that are configured to provide electrical paths for power and/or ground. The portion 552 (e.g., periphery portion) of the integrated device 105 may include may pillar interconnects (and/or coupled to pillar interconnects) that are configured to provide electrical paths for input/output (I/O) signals.

The portion 550 includes the plurality of pillar interconnects 408. The plurality of pillar interconnects 408 include a plurality of pillar interconnects 408aa, a plurality of pillar interconnects 408ab, a plurality of pillar interconnects 408ac and a plurality of pillar interconnects 408ad. The elongated portion of the pillar interconnects from the plurality of pillar interconnects 408aa may be oriented in a first diagonal direction (e.g., relative to a first edge 510 of the integrated device 105, towards a first corner 501 of the integrated device). The elongated portion of the pillar interconnects from the plurality of pillar interconnects 408ab may be oriented in a second diagonal direction (e.g., relative to a first edge 510 of the integrated device, towards a second corner 502 of the integrated device). The elongated portion of the pillar interconnects from the plurality of pillar interconnects 408ac may be oriented in a third diagonal direction (e.g., relative to a first edge 510 of the integrated device 105, towards a third corner 503 of the integrated device). The elongated portion of the pillar interconnects from the plurality of pillar interconnects 408ad may be oriented in a fourth diagonal direction (e.g., relative to a first edge 510 of the integrated device 105, towards a fourth corner 504 of the integrated device). In some implementations, the first diagonal direction may be opposite to the third diagonal direction. In some implementations, the second diagonal direction may be opposite to the fourth diagonal direction. In some implementations, the first diagonal direction may be orthogonal to the second diagonal direction and the fourth diagonal direction. In some implementations, the second diagonal direction may be orthogonal to the first diagonal direction and the third diagonal direction. It is noted that the plurality of pillar interconnects 408 may include pillar interconnects that may be oriented in a direction that is parallel or orthogonal to one or more edges of the integrated device 105. Thus, one or more pillar interconnects from the plurality of pillar interconnects 408 may be oriented and/or aligned in many different directions and are not limited to the example shown in FIG. 5.

The portion 552 includes the plurality of pillar interconnects 407. The plurality of pillar interconnects 407 include a plurality of pillar interconnects 407aa, a plurality of pillar interconnects 407ab, a plurality of pillar interconnects 407ac, a plurality of pillar interconnects 407ad, a plurality of pillar interconnects 407ae and a plurality of pillar interconnects 407af. The elongated portion of the pillar interconnects from the plurality of pillar interconnects 407aa may be oriented in a first diagonal direction (e.g., relative to a first edge 510 of the integrated device 105, towards a first corner 501 of the integrated device). The elongated portion of the pillar interconnects from the plurality of pillar interconnects 407ab may be oriented in a second diagonal direction (e.g., relative to a first edge 510 of the integrated device 105, towards a second corner 502 of the integrated device). The elongated portion of the pillar interconnects from the plurality of pillar interconnects 407c may be oriented in a third diagonal direction (e.g., relative to a first edge 510 of the integrated device 105, towards a third corner 503 of the integrated device). The elongated portion of the pillar interconnects from the plurality of pillar interconnects 407ad may be oriented in a fourth diagonal direction (e.g., relative to a first edge 510 of the integrated device 105, towards a fourth corner 504 of the integrated device). In some implementations, the first diagonal direction may be opposite to the third diagonal direction. In some implementations, the second diagonal direction may be opposite to the fourth diagonal direction. In some implementations, the first diagonal direction may be orthogonal to the second diagonal direction and the fourth diagonal direction. In some implementations, the second diagonal direction may be orthogonal to the first diagonal direction and the third diagonal direction.

The elongated portion of the pillar interconnects from the plurality of pillar interconnects 407ae may be oriented in a first direction that is parallel to an edge of the integrated device 105 (e.g., a first edge 510 of the integrated device 105). The elongated portion of the pillar interconnects from the plurality of pillar interconnects 407af may be oriented in a first direction that is perpendicular to an edge of the integrated device 105 (e.g., a first edge 510 of the integrated device 105).

It is noted that the configuration of the plurality of pillar interconnects shown in FIG. 5 is exemplary and is therefore not limited to the example shown in FIG. 5. Other implementations may have other configurations and/or arrangements of the plurality of pillar interconnects. For example, the integrated device 105 may include pillar interconnects that have circular planar shapes (e.g., non-elongated planar shapes). These pillar interconnects may be located in the portion 550 and/or the portion 552 of the integrated device 105.

In some implementations, the plurality of pillar interconnects 407 of an integrated device may be configured to be aligned with the plurality of landing pad interconnects 121b. In some implementations, the plurality of pillar interconnects 407aa may be aligned and/or oriented in a same direction as the plurality of landing pad interconnects 121ba. In some implementations, the plurality of pillar interconnects 407ab may be aligned and/or oriented in a same direction as the plurality of landing pad interconnects 121bb. In some implementations, the plurality of pillar interconnects 407ac may be aligned and/or oriented in a same direction as the plurality of landing pad interconnects 121bc. In some implementations, the plurality of pillar interconnects 407ad may be aligned and/or oriented in a same direction as the plurality of landing pad interconnects 121bd.

In some implementations, the plurality of pillar interconnects 408 of an integrated device may be configured to be aligned with the plurality of landing pad interconnects 121a. In some implementations, the plurality of pillar interconnects 408aa may be aligned and/or oriented in a same direction as the plurality of landing pad interconnects 121aa. In some implementations, the plurality of pillar interconnects 408ab may be aligned and/or oriented in a same direction as the plurality of landing pad interconnects 121ab. In some implementations, the plurality of pillar interconnects 408ac may be aligned and/or oriented in a same direction as the plurality of landing pad interconnects 121ac. In some implementations, the plurality of pillar interconnects 408ad may be aligned and/or oriented in a same direction as the plurality of landing pad interconnects 121ad.

In some implementations, the plurality of pillar interconnects 408 and/or the plurality of pillar interconnects 407 may have a pitch of about 105 micrometers in a first direction, and a minimum pitch of about 135 micrometers in a second direction. For example, in a direction along a length of a pillar interconnect, a minimum pitch (P_{L}) may be about 135 micrometers. In some implementations, in a direction along a width of a pillar interconnect, a minimum pitch (P_{W}) may be about 105 micrometers. The plurality of pillar interconnects 408 may include individual pillar interconnects that are longer, wider and/or larger than pillar interconnects from the plurality of pillar interconnects 407. However, it is noted that the pillar interconnects may have different dimensions and/or different minimum pitches. The configuration of the plurality of pillar interconnects 408 and/or the plurality of pillar interconnects 407 may be arranged in one or more rows of pillar interconnects. In some implementations, the configuration of the plurality of pillar interconnects 408 and/or the plurality of pillar interconnects 407 may be arranged in one or more staggered rows of pillar interconnects, such as shown in by the plurality of pillar interconnects 407.

The configuration of the plurality of pillar interconnects 408 and/or the plurality of pillar interconnects 407 that use an oblong planar shape and/or an elongated planar shape in combination with the diagonal orientation, helps provide interconnects that are closer to each other, which means higher density interconnects in the integrated device. This in turn helps provide high performance packages in a compact form factor. Moreover, orienting and/or aligning the pillar interconnects towards corner edges of the integrated device help provide a more robust package, as the orientation of the pillar interconnects and/or the orientation of the pillar interconnects help improve the stress that is absorbed by the package (e.g., during the coupling and/or bumping of the integrated device to the substrate).

An integrated device (e.g., 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Substrate

In some implementations, fabricating a substrate includes several processes. FIGS. 6A-6E illustrate an exemplary sequence for providing or fabricating a substrate. In some implementations, the sequence of FIGS. 6A-6E may be used to provide or fabricate a laminated substrate. The substrate that is fabricated in FIGS. 6A-6E may replace the substrate 102 of the disclosure.

It should be noted that the sequence of FIGS. 6A-6E may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 6A, illustrates a state after a carrier 601 is provided. The carrier 601 may include a core layer. The core layer may include seed layers on surfaces of the core layer.

Stage 2 illustrates a state after a plurality of interconnects 602 and a plurality of interconnects 604 are formed. The plurality of interconnects 602 may be coupled to a first surface (e.g., top surface) of the carrier 601. The plurality of interconnects 604 may be coupled to a second surface (e.g., bottom surface) of the carrier 601. A plating process, a masking process, an etching process and/or a strip process may be used to form the plurality of interconnects 602 and the plurality of interconnects 604. The plurality of interconnects 602 may be formed on a first seed layer of the carrier 601. The plurality of interconnects 604 may be formed on a second seed layer of the carrier 601.

The plurality of interconnects 602 may include a plurality of landing pad interconnects 602a and plurality of landing pad interconnects 602b. The plurality of landing pad interconnects 602a and/or the plurality of landing pad interconnects 602b may have an elongated planar shape and/or an oblong shape. The plurality of landing pad interconnects 602a may represent the plurality of landing pad interconnects 121a. The plurality of landing pad interconnects 602b may represent the plurality of landing pad interconnects 121b. The plurality of interconnects 604 may include a plurality of landing pad interconnects 604a and plurality of landing pad interconnects 604b. The plurality of landing pad interconnects 604a and/or the plurality of landing pad interconnects 604b may have an elongated planar shape and/or an oblong shape. The plurality of landing pad interconnects 604a may represent the plurality of landing pad interconnects 121a. The plurality of landing pad interconnects 604b may represent the plurality of landing pad interconnects 121b.

Stage 3, as shown in FIG. 6B, illustrates a state after a dielectric layer 610 and a dielectric layer 620 are provided. The dielectric layer 610 may be coupled to the first surface of the carrier 601. The dielectric layer 620 may be coupled to the second surface of the carrier 601. A deposition and/or a lamination process may be used to form the dielectric layer 610 and/or the dielectric layer 620. The dielectric layer 610 and/or the dielectric layer 620 may include prepreg, polymer and/or Ajinomoto Build-up Film (ABF).

Stage 4 illustrates a state after a plurality of cavities 611 are formed in the dielectric layer 610, and a plurality of cavities 621 are formed in the dielectric layer 620. An exposure and development process may be used to form the plurality of cavities 611 in the dielectric layer 610 and the plurality of cavities 621 in the dielectric layer 620. Different implementations may use different processes to form the plurality of cavities. The plurality of cavities 611 and/or the plurality of cavities 621 may be openings in dielectric layer(s).

Stage 5, as shown in FIG. 6C illustrates a state after a plurality of interconnects 612 are formed in the dielectric layer 610, and a plurality of interconnects 624 are formed in the dielectric layer 620. The plurality of interconnects 612 may be coupled to the plurality of interconnects 602. The plurality of interconnects 624 may be coupled to the plurality of interconnects 604. A plating process, a masking process, an etching process and/or a strip process may be used to form the plurality of interconnects 612 and/or the plurality of interconnects 624.

Stage 6 illustrates a state after additional build up layers are formed. For example, stage 6 illustrates a state after additional dielectric layers and additional interconnects are formed. For example, a dielectric layer 630 may be formed and coupled to the dielectric layer 610. A dielectric layer 640 may be formed and coupled to the dielectric layer 620. A lamination process and/or a deposition process may be used to form the dielectric layer 630 and the dielectric layer 640.

Stage 6 further illustrates a state after a plurality of interconnects 633 are formed in and over the dielectric layer 630, and after a plurality of interconnects 643 are formed in and over the dielectric layer 640. The plurality of interconnects 633 may be coupled to the plurality of interconnects 612. The plurality of interconnects 643 may be coupled to the plurality of interconnects 624. A plurality of cavities may be formed in the dielectric layer 630 and the dielectric layer 640 in a similar manner as described for forming a plurality of cavities in Stage 4 of FIG. 6C. The plurality of interconnects 633 and the plurality of interconnects 643 may be formed in a similar manner as described for fabricating a plurality of interconnects in Stage 5 of FIG. 6C. The plurality of interconnects 633 may include landing pad interconnects with elongated planar shapes and/or oblong planar shapes. The plurality of interconnects 643 may include landing pad interconnects with elongated planar shapes and/or oblong planar shapes.

Stage 7, as shown in FIG. 6D, illustrates a state after separation of the dielectric layers from the carrier 601. For example, the dielectric layer 610, the dielectric layer 630, the plurality of interconnects 602, the plurality of interconnects 612 and the plurality of interconnects 633 are separated from the carrier 601 to form a substrate 605 (e.g., coreless substrate). In another example, the dielectric layer 620, the dielectric layer 640, the plurality of interconnects 604, the plurality of interconnects 624 and the plurality of interconnects 643 are separated from the carrier 601 to form a substrate 102 (e.g., coreless substrate). The substrate 605 and/or the substrate 606 may be used instead of the substrate 102.

Stage 8, as shown in FIG. 6E, illustrates a state after a solder resist layer 124 and a solder resist layer 126 are formed on the substrate 102. A deposition process and/or a lamination process may be used to form the solder resist layer 124 and/or the solder resist layer 126.

### Exemplary Flow Diagram of a Method for Fabricating a Substrate

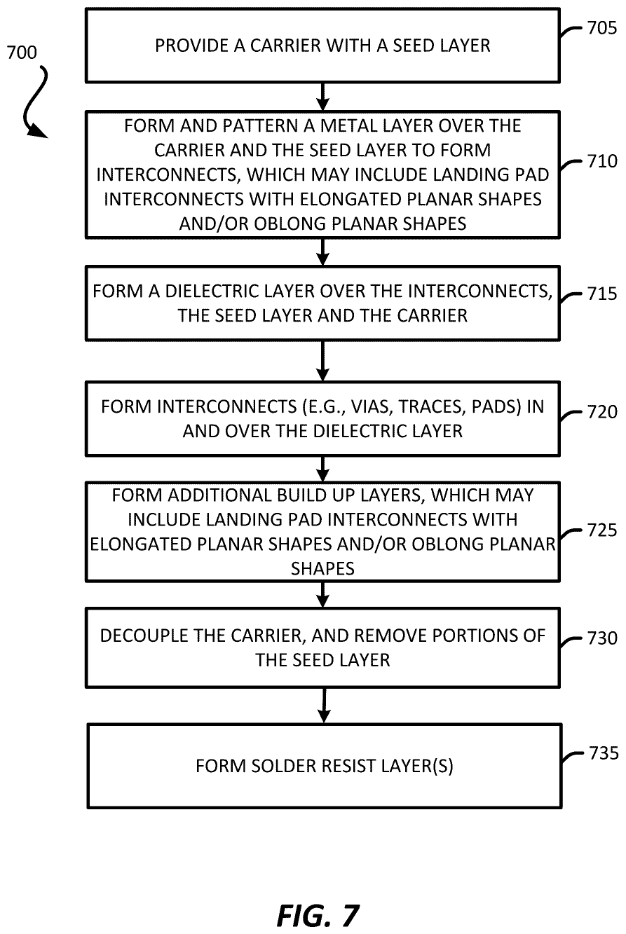

In some implementations, fabricating a substrate includes several processes. FIG. 7 illustrates an exemplary flow diagram of a method 700 for providing or fabricating a substrate. In some implementations, the method 700 of FIG. 7 may be used to provide or fabricate a substrate.

It should be noted that the method 700 of FIG. 7 may combine one or more processes in order to simplify and/or clarify the method for providing or fabricating a substrate. In some implementations, the order of the processes may be changed or modified.

The method provides (at 705) a carrier. The carrier may include seed layers. Stage 1 of FIG. 6A, illustrates and describes an example of a state after a carrier 601 is provided. The carrier 601 may include a core layer. The core layer may include seed layers on surfaces of the core layer.

The method forms (at 710) a plurality of interconnects on the carrier and/or the seed layer(s). Stage 2 of FIG. 6A, illustrates and describes an example of a state after a plurality of interconnects 602 and a plurality of interconnects 604 are formed. The plurality of interconnects 602 may be coupled to a first surface (e.g., top surface) of the carrier 601. The plurality of interconnects 604 may be coupled to a second surface (e.g., bottom surface) of the carrier 601. A plating process, a masking process, an etching process and/or a strip process may be used to form the plurality of interconnects 602 and the plurality of interconnects 604. The plurality of interconnects 602 may be formed on a first seed layer of the carrier 601. The plurality of interconnects 604 may be formed on a second seed layer of the carrier 601.

The plurality of interconnects 602 may include a plurality of landing pad interconnects 602a and plurality of landing pad interconnects 602b. The plurality of landing pad interconnects 602a and/or the plurality of landing pad interconnects 602b may have an elongated planar shape and/or an oblong shape. The plurality of landing pad interconnects 602a may represent the plurality of landing pad interconnects 121a. The plurality of landing pad interconnects 602b may represent the plurality of landing pad interconnects 121b. The plurality of interconnects 604 may include a plurality of landing pad interconnects 604a and plurality of landing pad interconnects 604b. The plurality of landing pad interconnects 604a and/or the plurality of landing pad interconnects 604b may have an elongated planar shape and/or an oblong shape. The plurality of landing pad interconnects 604a may represent the plurality of landing pad interconnects 121a. The plurality of landing pad interconnects 604b may represent the plurality of landing pad interconnects 121b.

The method forms (at 715) at least one dielectric layer over the plurality of interconnects, the seed layer(s) and/or the carrier. Stage 3 of FIG. 6B, illustrates and describes an example of a state after a dielectric layer 610 and a dielectric layer 620 are provided. The dielectric layer 610 may be coupled to the first surface of the carrier 601. The dielectric layer 620 may be coupled to the second surface of the carrier 601. A deposition and/or a lamination process may be used to form the dielectric layer 610 and/or the dielectric layer 620. The dielectric layer 610 and/or the dielectric layer 620 may include prepreg, polymer and/or Ajinomoto Build-up Film (ABF).

The method forms (at 720) interconnects in and over the dielectric layer. For example, via interconnects, trace interconnects and/or pad interconnects may be formed as the interconnects. Forming the plurality of interconnects may include forming a plurality of cavities in the dielectric layer(s). Stage 4 of FIG. 6B, illustrates and describes an example of a state after a plurality of cavities 611 are formed in the dielectric layer 610, and a plurality of cavities 621 are formed in the dielectric layer 620. An exposure and development process may be used to form the plurality of cavities 611 in the dielectric layer 610 and the plurality of cavities 621 in the dielectric layer 620. Different implementations may use different processes to form the plurality of cavities.

Stage 5 of FIG. 6C, illustrates and describes an example of a state after a plurality of interconnects 612 are formed in the dielectric layer 610, and a plurality of interconnects 624 are formed in the dielectric layer 620. The plurality of interconnects 612 may be coupled to the plurality of interconnects 602. The plurality of interconnects 624 may be coupled to the plurality of interconnects 604. A plating process, a masking process, an etching process and/or a strip process may be used to form the plurality of interconnects 612 and/or the plurality of interconnects 624.

The method forms (at 725) additional build up layers. Stage 6 of FIG. 6C, illustrates and describes an example of a state after additional build up layers are formed. For example, stage 6 illustrates a state after additional dielectric layers and additional interconnects are formed. For example, a dielectric layer 630 may be formed and coupled to the dielectric layer 610. A dielectric layer 640 may be formed and coupled to the dielectric layer 620. A lamination process and/or a deposition process may be used to form the dielectric layer 630 and the dielectric layer 640.

Stage 6 of FIG. 6C, further illustrates and describes an example of a state after a plurality of interconnects 633 are formed in and over the dielectric layer 630, and after a plurality of interconnects 643 are formed in and over the dielectric layer 640. The plurality of interconnects 633 may be coupled to the plurality of interconnects 612. The plurality of interconnects 643 may be coupled to the plurality of interconnects 624. A plurality of cavities may be formed in the dielectric layer 630 and the dielectric layer 640 in a similar manner as described for forming a plurality of cavities in Stage 4 of FIG. 6C. The plurality of interconnects 633 and the plurality of interconnects 643 may be formed in a similar manner as described for fabricating a plurality of interconnects in Stage 5 of FIG. 6C. The plurality of interconnects 633 may include landing pad interconnects with elongated planar shapes and/or oblong planar shapes. The plurality of interconnects 643 may include landing pad interconnects with elongated planar shapes and/or oblong planar shapes.

The method decouples (at 730) the carrier from the dielectric layers. The method may further remove portions of the seed layer(s). Stage 7 of FIG. 6D, illustrates and describes an example of a state after separation of the dielectric layers from the carrier 601. For example, the dielectric layer 610, the dielectric layer 630, the plurality of interconnects 602, the plurality of interconnects 612 and the plurality of interconnects 633 are separated from the carrier 601 to form a substrate 605 (e.g., coreless substrate). In another example, the dielectric layer 620, the dielectric layer 640, the plurality of interconnects 604, the plurality of interconnects 624 and the plurality of interconnects 643 are separated from the carrier 601 to form a substrate 606 (e.g., coreless substrate). The substrate 605 and/or the substrate 606 may be used instead of the substrate 102, in the package 100.

The method may further form (at 735) solder resist layer(s) on the substrate. In some implementations, once separation occurs, one or more solder resist layers may be formed on surface(s) of the substrate 605 and/or the substrate 606. Stage 8 of FIG. 6E, illustrates and describes an example of a state after a solder resist layer 124 and a solder resist layer 126 are formed on the substrate 102. A deposition process and/or a lamination process may be used to form the solder resist layer 124 and/or the solder resist layer 126.

### Exemplary Sequence for Fabricating an Integrated Device

In some implementations, fabricating an integrated device includes several processes. FIGS. 8A-8C illustrate an exemplary sequence for providing or fabricating an integrated device. In some implementations, the sequence of FIGS. 8A-8C may be used to provide or fabricate the integrated device 400. However, the process of FIGS. 8A-8C may be used to fabricate any integrated device described in the disclosure.

It should be noted that the sequence of FIGS. 8A-8C may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 8A, illustrates a state after a wafer 800 is provided. The wafer 800 may include un-diced integrated devices. The wafer 800 may include a die substrate portion 402, a die interconnection portion 404, a plurality of pad interconnects 403, a passivation layer 406, as described above in at least FIG. 4.

Stage 2 illustrates a state after a seed layer is formed over the wafer 800. The seed layer 470 may be an under bump metallization interconnect. The seed layer 470 may be formed over the passivation layer 406 and the plurality of pad interconnects 403. The seed layer may include copper (Cu). A sputtering process may be used to form the seed layer 470.

Stage 3, as shown in FIG. 8B, illustrates a state after a photo resist layer 810 is formed over the wafer 800. For example, the photo resist layer 810 may be formed over the seed layer 470 (e.g., over the under bump metallization interconnect). The photo resist layer 810 may be patterned to include a plurality of openings 811 in the photo resist layer 810. The photo resist layer 810 may be coated over the wafer 800. A photolithography process may be used to form and define the pattern of the photo resist layer 810. For example, an exposure process and development process may be used to form the plurality of openings 811 in the photo resist layer 810. The plurality of openings 811 may be located over the plurality of pad interconnects 403.

Stage 4 illustrates a state after the plurality of pillar interconnects 407 and a plurality of pillar interconnects 408 are formed and coupled to the seed layer 470. A plating process may be used to form the plurality of pillar interconnects 407 and the at least one pillar interconnect 408. The plurality of pillar interconnects 407 and the plurality of pillar interconnects 408 may be formed in the plurality of openings 811 of the photo resist layer 810. The pillar interconnect 407a may be coupled to the pad interconnect 403a, through the seed layer 470. The pillar interconnect 407b may be coupled to the pad interconnect 403b, through the seed layer 470. The pillar interconnect 408a may be coupled to the pad interconnect 403c, through the seed layer 470. The pillar interconnect 408b may be coupled to the pad interconnect 403d, through the seed layer 470. The plurality of pillar interconnects 407 and/or the plurality of pillar interconnects 408 may include an elongated planar shape and/or an oblong planar shape.

Stage 5, as shown in FIG. 8C, illustrates a state after solder interconnect 409 are formed and coupled to the plurality of pillar interconnects 407 and the at least one pillar interconnect 408. A pasting process may be used to form the plurality of solder interconnects 409 in openings of the photo resist layer 810.

Stage 6 illustrates a state after the photo resist layer 810 is removed. Stage 6 also illustrates a state after portions of the seed layer 470 are removed. An etching process may be used to remove portions of the seed layer 470. The portions of the seed layer 470 that are removed are portions that are not covered by the plurality of pillar interconnects 407 and/or the at least one pillar interconnect 408. Stage 6 may illustrate an example of the integrated device 400.

### Exemplary Flow Diagram of a Method for Fabricating an Integrated Device

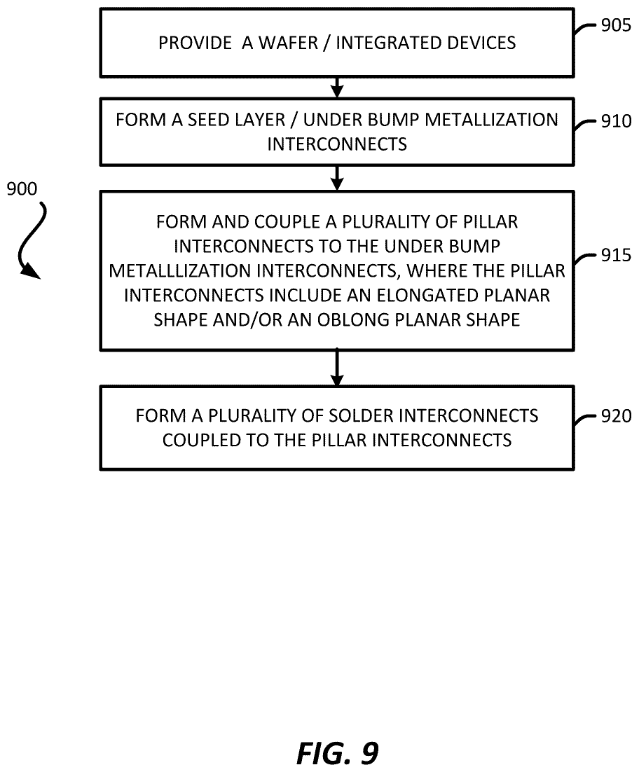

In some implementations, fabricating an integrated device includes several processes. FIG. 9 illustrates an exemplary flow diagram of a method 900 for providing or fabricating an integrated device that includes an alignment structure In some implementations, the method 900 of FIG. 9 may be used to provide or fabricate the integrated device of the disclosure. For example, the method 900 of FIG. 9 may be used to fabricate the integrated device 400.

It should be noted that the method 900 of FIG. 9 may combine one or more processes in order to simplify and/or clarify the method for providing or fabricating an integrated device. In some implementations, the order of the processes may be changed or modified.

The method provides (at 905) a wafer comprising an integrated device. Stage 1 of FIG. 8A, illustrates and describes an example of a state after a wafer 800 is provided. The wafer 800 may include a die substrate portion 402, a die interconnection portion 404, a plurality of pad interconnects 403, a passivation layer 406, as described above in at least FIG. 4.

The method forms (at 910) a seed layer. Stage 2 of FIG. 8A, illustrates and describes an example of a state after a seed layer is formed over the wafer 800. The seed layer 470 may be an under bump metallization interconnect. The seed layer 470 may be formed over the passivation layer 406 and the plurality of pad interconnects 403. The seed layer may include copper (Cu). A sputtering process may be used to form the seed layer 470.

The method forms (at 915) a plurality of pillar interconnects and at least one pillar interconnect configured as an alignment pillar. Stage 3 of FIG. 8B, illustrates and describes an example of a state after a photo resist layer 810 is formed over the wafer 800. For example, the photo resist layer 810 may be formed over the seed layer 470 (e.g., over the under bump metallization interconnect). The photo resist layer 810 may be patterned to include a plurality of openings 811 in the photo resist layer 810. The photo resist layer 810 may be coated over the wafer 800. A photolithography process may be used to form and define the pattern of the photo resist layer 810. For example, an exposure process and development process may be used to form the plurality of openings 811 in the photo resist layer 810. The plurality of openings 811 may be located over the plurality of pad interconnects 403.

Stage 4 of FIG. 8B, illustrates and describes an example of a state after the plurality of pillar interconnects 407 and a plurality of pillar interconnects 408 are formed and coupled to the seed layer 470. A plating process may be used to form the plurality of pillar interconnects 407 and the plurality of pillar interconnects 408. The plurality of pillar interconnects 407 and the plurality of pillar interconnects 408 may be formed in the plurality of openings 811 of the photo resist layer 810. The pillar interconnect 407a may be coupled to the pad interconnect 403a, through the seed layer 470. The pillar interconnect 407b may be coupled to the pad interconnect 403b, through the seed layer 470. The pillar interconnect 408a may be coupled to the pad interconnect 403c, through the seed layer 470. The pillar interconnect 408b may be coupled to the pad interconnect 403d, through the seed layer 470. The plurality of pillar interconnects 407 and/or the plurality of pillar interconnects 408 may include an elongated planar shape and/or an oblong planar shape.

The method forms and couples (at 920) a plurality of solder interconnects to the plurality of pillar interconnects and the at least one alignment pillar. Stage 5 of FIG. 8C, illustrates and describes an example of a state after solder interconnect 409 are formed and coupled to the plurality of pillar interconnects 407 and the at least one pillar interconnect 408. A pasting process may be used to form the plurality of solder interconnects 409 in openings of the photo resist layer 810.

The method may remove a photo resist layer after forming the plurality of solder interconnects. Stage 6 of FIG. 8C, illustrates and describes an example of a state after the photo resist layer 810 is removed. Stage 6 also illustrates a state after portions of the seed layer 470 are removed. An etching process may be used to remove portions of the seed layer 470. The portions of the seed layer 470 that are removed are portions that are not covered by the plurality of pillar interconnects 407 and/or the at least one pillar interconnect 408. Stage 6 may illustrate an example of the integrated device 400.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

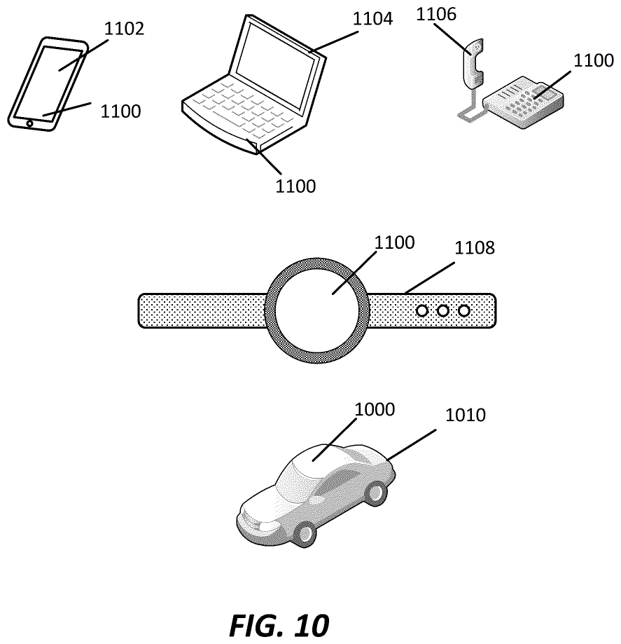

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-2, 3A-3B, 4, 5, 6A-6E, 7, 8A-8C and 9-10 may be rearranged and/or combined into a single component, process, feature or function or embodied in several components, processes, or functions. Additional elements, components, processes, and/or functions may also be added without departing from the disclosure. It should also be noted FIGS. 1-2, 3A-3B, 4, 5, 6A-6E, 7, 8A-8C and 9-10 and its corresponding description in the present disclosure is not limited to dies and/or ICs. In some implementations, FIGS. 1-2, 3A-3B, 4, 5, 6A-6E, 7, 8A-8C and 9-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a substrate comprising at least one dielectric layer; and a plurality of interconnects comprising a first plurality of landing pad interconnects, wherein at least one landing pad interconnect from the first plurality of landing pad interconnects has an elongated planar shape; and a second plurality of landing pad interconnects, wherein at least one landing pad interconnect from the second plurality of landing pad interconnects has an elongated planar shape; and an integrated device coupled to the first plurality of landing pad interconnects and the second plurality of landing pad interconnects.
Aspect 2: The package of aspect 1, wherein the integrated device is coupled to the first plurality of landing pad interconnects through a first plurality of pillar interconnects and a first plurality of solder interconnects.
Aspect 3: The package of aspect 2, wherein the integrated device is coupled to the second plurality of landing pad interconnects through a second plurality of pillar interconnects and a second plurality of solder interconnects.
Aspect 4: The package of aspects 1 through 3, wherein the substrate further comprises a solder resist layer.
Aspect 5: The package of aspect 4, wherein the solder resist layer comprises a first plurality of openings in the solder resist layer, and wherein at least one opening from the first plurality of openings includes an elongated planar shape.
Aspect 6: The package of aspect 5, wherein the solder resist layer comprises a second plurality of openings in the solder resist layer, and wherein at least one opening from the second plurality of openings includes an elongated planar shape.
Aspect 7: The package of aspects 1 through 6, wherein the elongated planar shape includes an elliptical planar shape and/or an elongated circular planar shape.
Aspect 8: The package of aspects 1 through 7, wherein at least one landing pad interconnect from the first plurality of landing pad interconnects is configured to provide at least one electrical path for power.
Aspect 9: The package of aspects 1 through 8, wherein at least one landing pad interconnect from the first plurality of landing pad interconnects is configured to provide at least one electrical path for ground.
Aspect 10: The package of aspects 1 through 9, wherein the second plurality of landing pad interconnects are configured to provide at least one electrical path for input and/or output signals.
Aspect 11: The package of aspects 1 through 10, wherein the elongated planar shape has a length and a width, and wherein the length is greater than the width.
Aspect 12: The package of aspects 1 through 11, wherein the integrated device comprises a plurality of pillar interconnects, and wherein the integrated device is coupled to the plurality of landing pad interconnects through the plurality of pillar interconnects and a plurality of solder interconnects.
Aspect 13: The package of aspect 12, wherein the plurality of pillar interconnects comprise a first plurality of pillar interconnects, where at least one pillar interconnect from the first plurality of pillar interconnects comprises an elongated planar shape; and a second plurality of pillar interconnects, where at least pillar interconnect from the second plurality of pillar interconnects comprises an elongated planar shape.
Aspect 14: The package of aspect 13, wherein the first plurality of pillar interconnects are configured to provide electrical paths for power and/or ground, and wherein the second plurality of pillar interconnects are configured to provide electrical paths for input/output (I/O) signals.
Aspect 15: The package of aspects 1 through 14, wherein the first plurality of landing pad interconnects are arranged in rows and/or staggered rows.
Aspect 16: The package of aspects 1 through 15, wherein a first set of landing pad interconnects from the first plurality of landing pad interconnects are oriented in a direction towards a corner of the substrate.
Aspect 17: An integrated device comprising a die substrate; a die interconnection portion coupled to the die substrate; a plurality of pad interconnects coupled to the die interconnection portion; and a plurality of pillar interconnects coupled to the plurality of pad interconnects, wherein the plurality of pillar interconnects comprise: a first plurality of pillar interconnects, wherein at least pillar interconnect from the first plurality of pillar interconnects has an elongated planar shape; and a second plurality of pillar interconnects, wherein at least pillar interconnect from the second plurality of pillar interconnects has an elongated planar shape.
Aspect 18: The integrated device of aspect 17, wherein the first plurality of pillar interconnects are configured to provide electrical paths for power and/or ground, and wherein the second plurality of pillar interconnects are configured to provide electrical paths for input/output (I/O) signals.
Aspect 19: The integrated device of aspects 17 through 18, wherein the first plurality of pillar interconnects include at least one pillar interconnect that has a first planar size, and wherein the second plurality of pillar interconnects include at least one pillar interconnect that has a second planar size that is different from the first planar size.
Aspect 20: The integrated device of aspects 17 through 19, wherein the first plurality of pillar interconnects are arranged in rows and/or staggered rows, and wherein a first set of pillar interconnects from the first plurality of pillar interconnects are oriented in a direction towards a corner of the integrated device.
Aspect 21: The integrated device of aspects 17 through 20, wherein the integrated device is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 22: The package of aspects 1 through 16, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer; and
a plurality of interconnects comprising:
a first plurality of landing pad interconnects, wherein at least one landing pad interconnect from the first plurality of landing pad interconnects has an elongated planar shape; and
a second plurality of landing pad interconnects, wherein at least one landing pad interconnect from the second plurality of landing pad interconnects has an elongated planar shape; and
an integrated device coupled to the first plurality of landing pad interconnects and the second plurality of landing pad interconnects.

2. The package of claim 1, wherein the integrated device is coupled to the first plurality of landing pad interconnects through a first plurality of pillar interconnects and a first plurality of solder interconnects.

3. The package of claim 2, wherein the integrated device is coupled to the second plurality of landing pad interconnects through a second plurality of pillar interconnects and a second plurality of solder interconnects.

4. The package of claim 1, wherein the substrate further comprises a solder resist layer.

5. The package of claim 4,
wherein the solder resist layer comprises a first plurality of openings in the solder resist layer, and
wherein at least one opening from the first plurality of openings includes an elongated planar shape.

6. The package of claim 5,
wherein the solder resist layer comprises a second plurality of openings in the solder resist layer, and
wherein at least one opening from the second plurality of openings includes an elongated planar shape.

7. The package of claim 1, wherein the elongated planar shape includes an elliptical planar shape and/or an elongated circular planar shape.

8. The package of claim 1, wherein at least one landing pad interconnect from the first plurality of landing pad interconnects is configured to provide at least one electrical path for power.

9. The package of claim 1, wherein at least one landing pad interconnect from the first plurality of landing pad interconnects is configured to provide at least one electrical path for ground.

10. The package of claim 1, wherein the second plurality of landing pad interconnects are configured to provide at least one electrical path for input and/or output signals.

11. The package of claim 1,
wherein the elongated planar shape has a length and a width, and
wherein the length is greater than the width.

12. The package of claim 1,
wherein the integrated device comprises a plurality of pillar interconnects, and
wherein the integrated device is coupled to the plurality of landing pad interconnects through the plurality of pillar interconnects and a plurality of solder interconnects.

13. The package of claim 12, wherein the plurality of pillar interconnects comprise:
a first plurality of pillar interconnects, where at least one pillar interconnect from the first plurality of pillar interconnects comprises an elongated planar shape; and
a second plurality of pillar interconnects, where at least pillar interconnect from the second plurality of pillar interconnects comprises an elongated planar shape.

14. The package of claim 13,
wherein the first plurality of pillar interconnects are configured to provide electrical paths for power and/or ground, and
wherein the second plurality of pillar interconnects are configured to provide electrical paths for input/output (I/O) signals.

15. The package of claim 1, wherein the first plurality of landing pad interconnects are arranged in rows and/or staggered rows.

16. The package of claim 1, wherein a first set of landing pad interconnects from the first plurality of landing pad interconnects are oriented in a direction towards a corner of the substrate.

17. An integrated device comprising:
a die substrate;
a die interconnection portion coupled to the die substrate;
a plurality of pad interconnects coupled to the die interconnection portion; and
a plurality of pillar interconnects coupled to the plurality of pad interconnects, wherein the plurality of pillar interconnects comprise:
a first plurality of pillar interconnects, wherein at least pillar interconnect from the first plurality of pillar interconnects has an elongated planar shape; and
a second plurality of pillar interconnects, wherein at least pillar interconnect from the second plurality of pillar interconnects has an elongated planar shape.

18. The integrated device of claim 17,
wherein the first plurality of pillar interconnects are configured to provide electrical paths for power and/or ground, and
wherein the second plurality of pillar interconnects are configured to provide electrical paths for input/output (I/O) signals.

19. The integrated device of claim 17,
wherein the first plurality of pillar interconnects include at least one pillar interconnect that has a first planar size, and
wherein the second plurality of pillar interconnects include at least one pillar interconnect that has a second planar size that is different from the first planar size.

20. The integrated device of claim 17,
wherein the first plurality of pillar interconnects are arranged in rows and/or staggered rows, and
wherein a first set of pillar interconnects from the first plurality of pillar interconnects are oriented in a direction towards a corner of the integrated device.
